(19) United States
(12) Patent Application Publication
(10) Pub. No.: US 2025/0125296 A1
(43) Pub. Date: Apr. 17, 2025

(54) Double Bump Design for Multiple Purpose IO Connections

(71) Applicants: Krishna Bharath Kolluru, Hillsboro, OR (US); Paul Rotker, Stow, MA (US); Jeffrey Erik Schulz, Milpitas, CA (US); MD Altaf Hossain, Portland, OR (US); Navindra Navaratnam, Portland, OR (US); Archanna Srinivasan, San Jose, CA (US)

(72) Inventors: Krishna Bharath Kolluru, Hillsboro, OR (US); Paul Rotker, Stow, MA (US); Jeffrey Erik Schulz, Milpitas, CA (US); MD Altaf Hossain, Portland, OR (US); Navindra Navaratnam, Portland, OR (US); Archanna Srinivasan, San Jose, CA (US)

(21) Appl. No.: 19/002,453

(22) Filed: Dec. 26, 2024

(51) Int. Cl. H01L 23/00; H01L 23/498; H01L 23/528; H01L 23/538; H01L 25/16; H10D 89/10

(52) U.S. Cl. CPC H01L 24/16; H01L 23/5385; H01L 23/5386; H01L 25/16; H10D 89/10; H01L 23/49816; H01L 23/5286; H01L 2224/16225; H01L 2924/1431

(57) ABSTRACT

Systems or methods of the present disclosure may provide a dual bump design to support both high voltage input/output (HVIO) connections and medium speed input/output (MSIO) connections. The present disclosure includes an MSIO lane that couples to a first bump that couples to MSIO pins, a second bump that couples to an HVIO circuit, and a ball grid array (BGA) ball. The present disclosure also includes a multiplexer that selectively couples the MSIO pins to the BGA ball or the HVIO circuit to the BGA ball based on user input. As such, the MSIO lane may provide MSIO connections, HVIO connections, or both.

### BACKGROUND

The present disclosure relates generally to integrated circuits, such as processors and/or field-programmable gate arrays (FPGAs). More particularly, the present disclosure relates to dual (e.g., double) bump designs for multiple purpose input/output (IO) connections within the integrated circuit device.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light, and not as admissions of prior art.

Integrated circuit devices (e.g., multi-chip packages) may be utilized for a variety of purposes or applications. As integrated circuits decrease in size using more advanced semiconductor manufacturing, the voltage levels used by these advanced integrated circuits also decreases. Many advanced integrated circuits may be able to support medium speed input/output (MSIO) communication, which uses sufficiently low voltage levels. Yet the same advanced integrated circuits may be unable to support high voltage input/output (HVIO), which is an older technology that is still in use that uses higher voltage levels than those found in many advanced integrated circuits.

### BRIEF DESCRIPTION OF THE DRAWINGS

Various aspects of this disclosure may be better understood upon reading the following detailed description and upon reference to the drawings in which:

FIG. 1 is a block diagram of an integrated circuit device, in accordance with an embodiment of the present disclosure;

FIG. 2 is a schematic diagram of an embodiment of the integrated circuit device of FIG. 1 with a first integrated circuit and a second integrated circuit, in accordance with an embodiment of the present disclosure;

FIG. 3 is a schematic diagram of an embodiment of the integrated circuit device of FIG. 1 with a first integrated circuit and a second integrated circuit coupled via an interposer, in accordance with an embodiment of the present disclosure;

FIG. 4 is a block diagram of a medium speed input/output (MSIO) lane of the first integrated circuit device of FIG. 2 implementing a dual bump design, in accordance with an embodiment of the present disclosure;

FIG. 5 is a schematic diagram of an embodiment of the integrated circuit device of FIG. 1 with a second integrated circuit disposed within and/or implemented by the interposer, in accordance with an embodiment of the present disclosure;

FIG. 6 is a schematic diagram of an embodiment of the integrated circuit device of FIG. 1 with a first integrated circuit and a second integrated circuit coupled via the interposer, in accordance with an embodiment of the present disclosure;

FIG. 7 is a schematic diagram of an embodiment of the integrated circuit device of FIG. 1 a first integrated circuit and a second integrated circuit coupled via the interposer, in accordance with an embodiment of the present disclosure;

FIG. 8 is a schematic diagram of an embodiment of the integrated circuit device of FIG. 1 a first integrated circuit and a second integrated circuit coupled via the interposer, in accordance with an embodiment of the present disclosure; and

FIG. 9 is a block diagram of a data processing system including the integrated circuit device of FIG. 1, in accordance with an embodiment of the present disclosure.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the phrase A “based on” B is intended to mean that A is at least partially based on B. Moreover, the term “or” is intended to be inclusive (e.g., logical OR) and not exclusive (e.g., logical XOR). In other words, the phrase A “or” B is intended to mean A, B, or both A and B.

As integrated circuits become smaller in size using more advanced semiconductor manufacturing processes, it may be beneficial to disaggregate high voltage input/output (HVIO) functionalities (e.g., HVIO circuits) from the silicon area of the advanced-node integrated circuits. For example, it may be desirable to implement the HVIO functionalities in a chiplet (e.g., die, tile) separate from one or more advanced integrated circuits of an integrated circuit device. For example, the HVIO circuit may be implemented in a chiplet. The HVIO chiplet may be coupled to an integrated circuit device. For example, the HVIO chiplet may be coupled to an input/output (IO) circuit, such as a medium speed input/output (MSIO) circuit, within the integrated circuit device via one or more bumps.

With the foregoing in mind, the present systems and techniques relate to embodiments for a dual bump design for multiple purpose input/output (IO) connections within an integrated circuit device. The disclosed embodiments include an MSIO lane with two bumps that isolate HVIO on-package input/output (OPIO) from MSIO IO. For example, a first bump may include an MSIO ball bump coupled to the MSIO IO and a second bump may include an HVIO OPIO bump coupled to the HVIO. The disclosed embodiments may include a multiplexer to selectively couple a bump of the two bumps to a BGA ball to form either MSIO connections, HVIO connections, or both. As such, the dual bump design may provide the flexibility to select between the MSIO applications, the HVIO applications, or both. By implementing the double bump design, the disclosed embodiments may reduce or eliminate package yield loss due to HVIO chiplet, increase flexibility of the integrated circuit device, reduce costs for manufacturing the integrated circuit device, and so on.

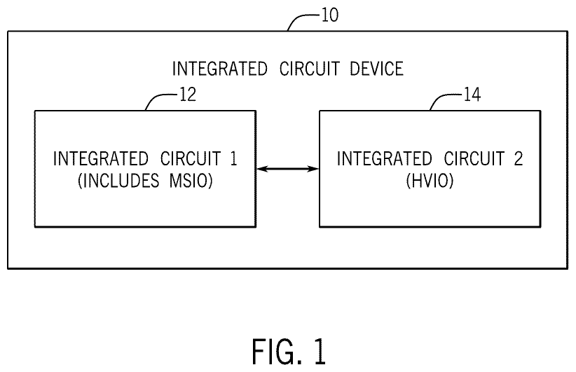

With the foregoing in mind, FIG. 1 illustrates a block diagram of an integrated circuit device (e.g., a multi-chip package) 10 to implement one or more functionalities. For example, the integrated circuit device 10 may include a first integrated circuit (e.g., chiplet, die, tile, integrated circuit device) 12 and a second integrated circuit (e.g., chiplet, die, tile, integrated circuit device) 14. In other examples, the integrated circuit device 10 may include multiple integrated circuits in a package and/or multiple integrated circuits in multiple packages communicating remotely (e.g., via wires or traces). The integrated circuit device 10 may implement one or more functionalities implemented by a designer.

The first integrated circuit 12 may operate as a programmable logic device, such as field programmable gate array (FPGA) device. For example, the first integrated circuit 12 may include a number of programmable logic elements having operation defined by configuration memory. The first integrated circuit 12 may be configurable to implement a design by a designer and perform one or more functions based on the design. The first integrated circuit 12 may include a power supply to provide a source of voltage and current to a power distribution network that distributes electrical power to various components of the first integrated circuit 12. The first integrated circuit 12 may include an input/output (IO) circuit. For example, the first integrated circuit 12 may include a medium speed input/output (MSIO) circuit to transmit signals, receive signals, and/or operate at a speed up to 3 gigahertz (GHz). While the application discusses the MSIO circuit, MSIO pins, and/or MSIO applications, it may be understood that the first integrated circuit 12 may implement any suitable IO circuit for any suitable IO applications.

The second integrated circuit 14 may implement higher-voltage functionalities. For example, the second integrated circuit 14 may implement an HVIO circuit and may operate at a speed of 100 megahertz (MHz) or greater. The second integrated circuit 14 may operate at higher voltage in comparison to the first integrated circuit 12. For example, the second integrated circuit 14 may handle and/or support operation at voltage ranges that exceed the operating range of the first integrated circuit 12. As referred to herein, high voltage may refer to voltage values (e.g., levels) that exceed the operating range of the first integrated circuit 12 and/or MSIO applications. For example, high voltage may include voltages in ranges of 1.8 volts (V) to 3.3V. For example, the second integrated circuit 14 may include high voltage input/output (HVIO) on-package communication, such as on-package input/output (OPIO), to receive high voltage signals and/or drive high voltage signals (e.g., loads) to other components of the integrated circuit device 10. In another example, the second integrated circuit 14 may provide protection features, such as over-voltage protection, short-circuit protection, electrostatic discharge protection, which may reduce or eliminate damage to the first integrated circuit 12 caused by voltage levels outside the range of the first integrated circuit 12, and so on. As discussed herein, it may be beneficial to implement the high voltage functionalities into an integrated circuit to reduce the size of the integrated circuit device 10.

The first integrated circuit 12 and the second integrated circuit 14 may be communicatively coupled within the integrated circuit device 10. The second integrated circuit 14 may provide an output to the first integrated circuit 12. For example, the first integrated circuit 12 and the second integrated circuit 14 may be coupled via a package substrate and one or more bumps. In another example, the first integrated circuit 12 and the second integrated circuit 14 may be coupled via an interposer and one or more bumps. Still in another example, the second integrated circuit 14 may be disposed within and/or implemented by the interposer and the first integrated circuit 12 may be mounted onto the interposer. Although the illustrated integrated circuit device 10 includes two integrated circuits, it may be understood that the integrated circuit device 10 may include any suitable number of integrated circuits.

The integrated circuit device 10 may implement a dual bump design for multiple purpose IO connections. For example, the first integrated circuit 12 may include an MSIO lane (e.g., IO lane) with dual bumps to isolate the MSIO IO from the HVIO OPIO. For example, the second integrated circuit 14 may be coupled to one or more MSIO pin(s) of the first integrated circuit 12 via an MSIO lane of the first integrated circuit 12 and the MSIO lane may selectively couple either the MSIO pins or the HVIO circuit to a ball grid array (BGA) ball to provide for MSIO connections, HVIO connections, or both. As such, the MSIO pin(s) may be coupled to the BGA ball and/or the HVIO circuit may be coupled to the BGA ball for package connectivity. As further discussed herein, the integrated circuit device 10 may include a multiplexer (e.g., mux) to support an MSIO BGA connection, an HVIO IPIO connection, or both.

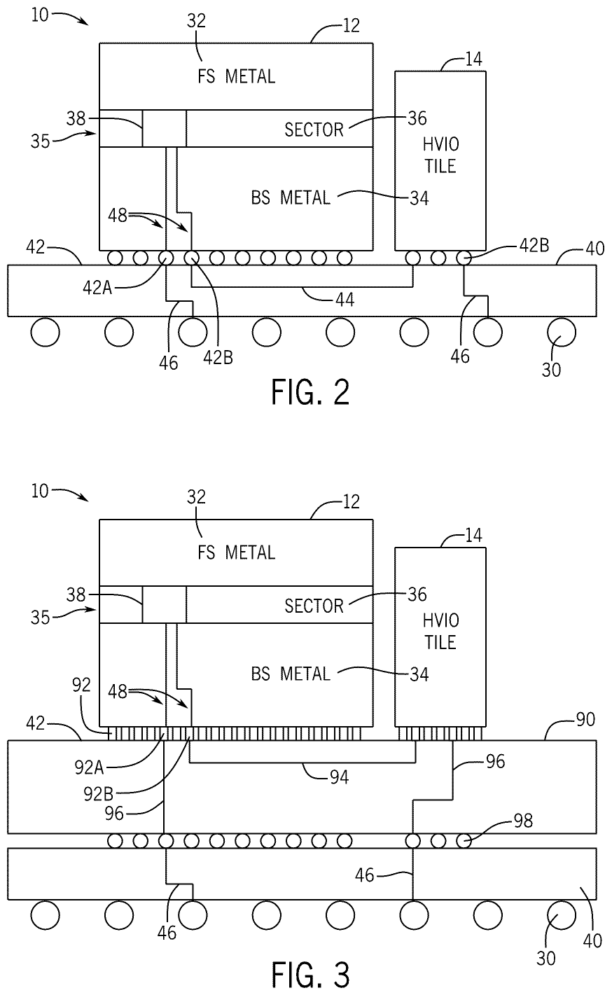

FIG. 2 a schematic diagram of an embodiment of the integrated circuit device 10 with the first integrated circuit 12 and the second integrated circuit 14. The schematic diagram of FIG. 2 illustrates a cross-sectional view of the first integrated circuit 12 implementing a dual bump design to support both HVIO connections and MSIO connections.

As discussed herein, the first integrated circuit 12 may include a programmable logic device, such as an FPGA. The first integrated circuit 12 may include frontside metal layers 32, backside metal layers 34, and a transistor (XTR) plane 35 between the frontside metal layers 32 and the backside metal layers 34. The frontside metal layers 32 and/or backside metal layers 34 may include one or more signal metals dedicated to signal transfer, components for implementing one or more functionalities of the first integrated circuit 12, and so on. For example, the backside metal layers 34 may include signal metals that form a pathway for signal transfer between components of the integrated circuit device 10 and/or off-package components. As used herein, the term “frontside” may refer to a frontside surface where a conventional integrated circuit may be fabricated, such as a side adjacent to or away from a carrier wafer, and the term “backside” may be an opposite surface of the substrate. Furthermore, the schematic diagram may be a simplified illustration omitting one or more components for the simplicity in discussing the first and second layers.

The XTR plane 35 may connect one or more sectors (e.g., programmable logic sectors) 36 and MSIO pins 38. Each sector 36 may be connected to an independent voltage regulator and a power supply. For example, each sector 36 may run via connections to the same supply that provides power control for each of the sectors 36. Each sector 36 may include MSIO pins 38 that may be coupled to the power supply via a BGA ball 30 and provide a voltage level lower than a maximum default voltage level of the sector 36. As such, the MSIO pins 38 may enable each sector 36 to establish an independent power domain within the first integrated circuit 12. For example, a first set MSIO pins 38 may enable a first sector 36 operating at a first voltage to communicate with a second sector 36 that may operate at a second voltage higher than the first voltage. In another example, each sector 36 may couple to two different power supplies. The MSIO pins 38 may handle different signal types, voltage levels, and/or communication protocols for the sector 36. For example, the MSIO pins 38 may be configurable to operate at different voltage levels and/or may include voltage scaling features to interface with components operating at lower or higher voltage domains.

As discussed herein, the second integrated circuit 14 may implement high voltage functionalities. For example, the second integrated circuit 14 may implement an HVIO circuit that handles operations and/or operates at a higher voltage level than the first integrated circuit 12.

The first integrated circuit 12 and the second integrated circuit 14 may be attached (e.g., mounted) on a package substrate 40 via one or more bumps 42. The one or more bumps 42 may include controlled collapse chip connection (C4) bumps. The integrated circuit device 10 may include any suitable number of C4 bumps. For example, the number of C4 bumps within the integrated circuit device 10 may be greater than the number of C4 bumps used for power delivery to the sectors 36. As such, the C4 bumps may extend beyond the MSIO pins 38 and protrude the sector 36. The sectors 36 may utilize more power and/or grounding bumps, as such the protrusion may not create any overhead for the sector 36.

The integrated circuit device 10 may include electronic connections to support communication (e.g., signal transfer) between the components (e.g., the first integrated circuit 12, the second integrated circuit 14) of the integrated circuit device 10 and/or with off-package components. For example, the package substrate 40 may include a first set of traces 44 to couple the first integrated circuit 12 and second integrated circuit 14 to components within the integrated circuit device 10. The first set of traces 44 may provide signal transfer between the first integrated circuit 12 and the second integrated circuit 14. The package substrate 40 may include a second set of traces 46 to couple the first integrated circuit 12 and the second integrated circuit 14 to one or more off-package components via the BGA balls 30. As illustrated, the second set of traces 46 may couple the first integrated circuit 12 to a first BGA ball 30 and/or the second integrated circuit 14 to the first BGA ball 30. The second integrated circuit 14 may be coupled to second BGA ball 30 to receive an input (e.g., input voltage) and/or a transmit an output to the off-package components. The first set of traces 44 and/or a second set of traces 46 may include fixed traces, configurable traces, or both.

The BGA balls 30 may facilitate signal transfer between components of the integrated circuit device 10 and off-package components, provide power delivery to the integrated circuit device 10, and/or grounding between the integrated circuit device 10 and a printed circuit board (PCB) that may be coupled to the BGA balls 30. For example, a BGA ball 30 may be coupled to the first integrated circuit 12 via the second set of traces 46. In another example, the BGA balls 30 be coupled to the second integrated circuit 14 via the first integrated circuit 12, the second set of traces 46, and the first set of traces 44.

The integrated circuit device 10 may implement a dual bump design to support the MSIO connections, the HVIO connections, the MSIO and HVIO connections, or any combination thereof. For example, the first integrated circuit 12 may be configurable to support any of the connections, thereby reducing complexity of the integrated circuit device 10. The first integrated circuit 12 may include an MSIO lane 48 formed by signal traces in the backside metal layers 34. The MSIO lane 48 may be coupled to two different bumps 42. The MSIO lane 48 may be coupled to a first bump 42A, thereby coupling the MSIO pins 38 to the BGA ball 30 for MSIO connections. The MSIO lane 48 may be coupled to a second bump 42B to receive an input and/or an output from the second integrated circuit 14 and/or couple the second integrated circuit 14 to the BGA balls 30. As such, the MSIO lane 48 may facilitate MSIO connections via the first bump 42A and HVIO connections via the second bump 42B. As further the MSIO lane 48 may selectively couple either the first integrated circuit 12 or the second integrated circuit 14 to the BGA ball 30. As such, a designer may implement a design on the first integrated circuit 12 that uses the MSIO pins 38 for HVIO connectivity, high speed data transfers, or both.

By way of example, the first integrated circuit 12 may include 50 MSIO lanes 48. The 50 MSIO lanes 48 may support 50 MSIO connections, 50 HVIO connections, or a combination of HVIO and MSIO connections. In another example, the 50 MSIO lanes 48 may be configurable to support 25 MSIO connections (e.g., MSIO BGA connections) and 25 HVIO connections (e.g., HVIO OPIO connections). By supporting both MSIO connections and HVIO connections, the design complexity of the first integrated circuit 12 may decrease and flexibility of the first integrated circuit 12 may increase. It may be understood that the first integrated circuit 12 may include any suitable number of MSIO lanes 48 to support any suitable number of MSIO connections, HVIO connections, or both. For example, the first integrated circuit 12 may include 10 MSIO lanes 48, 12 MSIO lanes 48, 15 MSIO lanes 48, 20 MSIO lanes 48, 25 MSIO lanes 48, and so on.

In certain instances, the second integrated circuit 14 may fail (e.g., yield loss). The MSIO lane 48 may maintain connection with the first bump 42A and/or the BGA ball 30, thereby maintaining the MSIO connection and providing a functionality to the MSIO lane 48. As such, the integrated circuit device 10 may not experience yield loss due to yield loss of the second integrated circuit 14.

FIG. 3 is a schematic diagram of an embodiment of the integrated circuit device 10 with the first integrated circuit 12 and the second integrated circuit 14. The schematic diagram of FIG. 3 illustrates a cross-sectional view of the first integrated circuit 12 implementing the dual bump design to support both HVIO connections, MSIO connections, or both via an interposer 90.

As illustrated, the first integrated circuit 12 and the second integrated circuit 14 may be positioned side-by-side and connected to one another via an interposer 90 in a 2.5 dimensional (2.5D) form. In other instances, the integrated circuit device 10 may include additional integrated circuits in a 3-dimensional (3D) form. The interposer 90 may include an active interposer, a passive interposer, a bridge (e.g., an embedded multi-die interconnect bridge (EMIB)), or any combination thereof.

The first integrated circuit 12 and the second integrated circuit 14 may be attached to the interposer 90 via one or more microbumps 92. Although microbumps 92 are discussed throughout, any bonding techniques that are suitable for coupling the first integrated circuit 12 and the second integrated circuit 14 to the interposer 90 may be used. For example, the first integrated circuit 12 and/or the second integrated circuit 14 may be coupled to the interposer 90 via high bandwidth interfaces (e.g., 2.5 dimension (2.5D) interfaces, interconnect bridges, microbump interfaces) and/or any other suitable multi-channel interconnect. The microbumps 92 may couple to an interface of first integrated circuit 12 (e.g., a fabric or FPGA interface and an interface of the interposer 90).

The interposer 90 may facilitate signal transfer and power delivery between the integrated circuits of the integrated circuit device 10. For example, the interposer 90 may include a first set of traces (e.g., a third set of traces) 94 coupling the first integrated circuit 12 to the second integrated circuit 14 via the microbumps 92 and a second set of traces (e.g., a fourth set of traces) 96 coupling the first integrated circuit 12 and the second integrated circuit 14 to the package substrate 40 via package substrate build-ups (PSBs) 98, respectively. The PSBs 98 may couple the interposer 90 to the package substrate 40 to provide power and/or ground signals between the two.

As discussed herein, the integrated circuit device 10 may implement a dual bump design in the sectors 36 to support the MSIO connections, the HVIO connections, the MSIO and HVIO connections, or any combination thereof. As illustrated, the first integrated circuit 12 may include the MSIO lane 48 that couples the MSIO pins 38 to a first microbump 92A. The MSIO lane 48 may couple to the second integrated circuit 14 via a second microbump 92B. As such, the MSIO lane 48 receives an output from the second integrated circuit 14. The MSIO lane 48 may selectively couple either the MSIO pins 38 to the BGA ball 30 via the first microbump 92A or the second integrated circuit 14 to the BGA ball 30 via the second microbump 92A. As such, the MSIO lane 48 may provide MSIO connections, HVIO connections, or both. The microbumps 92 may be small in comparison to the MSIO lane 48, and as such, may not extend past the width of the MSIO lane 48.

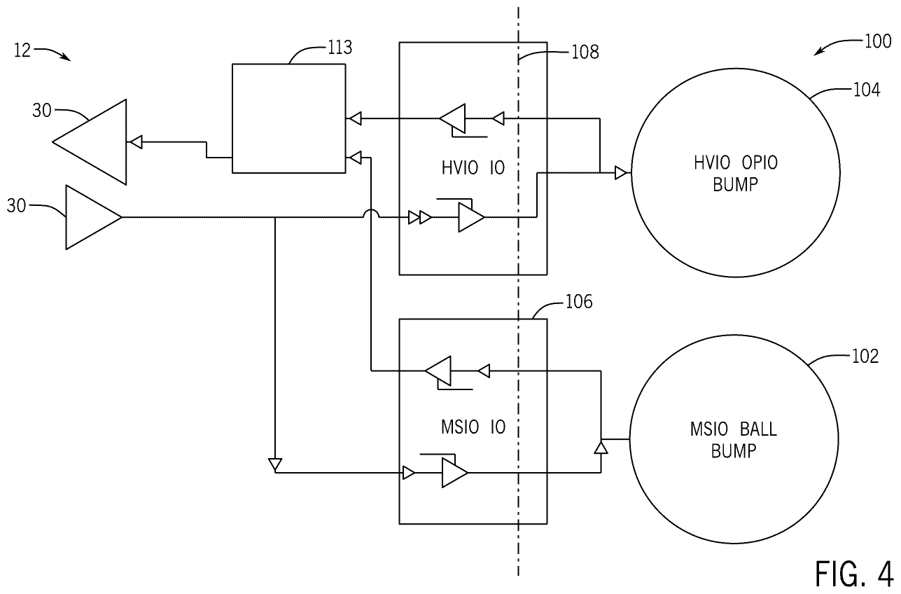

With the foregoing in mind, FIG. 4 is a block diagram of an MSIO lane 48 of the first integrated circuit 12 implementing a dual bump design 100. The schematic diagram illustrates a simplified view of the IO architecture of the MSIO lane 48 selectively coupling to an input from a first bump 102 and an input from a second bump 104 to facilitate the HVIO connections, the MSIO connections, or both. The MSIO lane 48 may support two bumps by isolating the HVIO OPIO from in-package MSIO.

The first bump 102 may include an MSIO ball bump and the second bump 104 may include an HVIO OPIO bump. The first bump 102 and/or the second bump 104 may include a C4 bump, such as the first bump 42A and/or the second bump 42B described with respect to FIG. 2, and/or a microbump, such as the first microbump 92A or the second microbump 92B described with respect to FIG. 3. The first bump 102 may be coupled to an MSIO interface 106 that facilitates MSIO connections and the second bump 104 may be coupled to the HVIO OPIO 108 that facilitates HVIO connections. The MSIO interface 106 may provide a voltage to the first integrated circuit 12 and/or provide an output from the first integrated circuit 12 to the BGA ball 30 for off-package communication. The HVIO interface 108 may provide a voltage to the second integrated circuit 14 and/or provide an output from the second integrated circuit 14 for off-package communication.

The MSIO interface 106 and the HVIO interface 108 may be coupled to a multiplexer (mux) 113. The multiplexer 113 may receive an input from a BGA ball 30 as an input and receive both an input of the MSIO interface 106 and an input of the HVIO interface 108 as outputs. The multiplexer 113 may selectively couple the input of either the first bump 102 or the second bump 104 to the BGA ball 30. As such, the input of the MSIO interface 106 and/or the HVIO interface 108 may receive a voltage from the BGA ball 30. The MSIO interface 106 may provide an output from the MSIO pins 38 to the BGA ball 30 for off-package communication. The HVIO interface 108 may provide an output from the second integrated circuit 14 to another BGA ball 30 for off-package communication. As such, the dual bump design may support MSIO connections, HVIO connections, or both.

In an example, the multiplexer 113 may selectively couple to either the MSIO interface 106 or the HVIO interface 108 based on user input. For example, the user input may request MSIO connectivity, as such the multiplexer 113 may couple the MSIO interface 106 to the BGA ball 30. In another example, the user input may request HVIO connectivity and the multiplexer 113 may couple the HVIO interface 108 to the BGA ball 30.

The multiplexer 113 may include an analog multiplexer and/or a digital multiplexer. For example, the multiplexer 113 may include an analog multiplexer that operates at high voltages, such as the voltage levels of the HVIO interface 108. In another example, the multiplexer 113 may include a digital multiplexer that varies a supply (e.g., voltage supply) based on an input. When the digital multiplexer is coupled to the HVIO interface 108, the multiplexer 113 may operate at a high voltage similar to the high voltage of the HVIO interface 108, and the multiplexer 113 may operate at a lower voltage when the multiplexer 113 may be coupled to the MSIO interface 102. In an embodiment, the multiplexer 113 may be coupled to power control circuitry (e.g., programmable power circuitry) that adjusts the supply based on the input to the multiplexer 113. Additionally or alternatively, the multiplexer 113 may be coupled to a voltage regulator that provides converts a voltage into a range of voltages for the multiplexer 113. For example, the voltage regulator may convert 3.3V into a first voltage range corresponding to the high voltage of the HVIO interface 108 and/or a second voltage range corresponding to a lower voltage of the MSIO interface 102. By way of illustrative example, the first voltage range may include 1.3V-3.3V and the second voltage range may include 0-1.5V. As such, the multiplexer 113 may operate within a voltage range of the HVIO interface 108, the MSIO interface 102, or both.

In another example, the designer may implement more MSIO connections within the integrated circuit device 10 than HVIO connections for a functionality, then the multiplexer 113 may configure more MSIO lanes 48 for MSIO connections than HVIO connections. In another example, the designer may implement more HVIO connections than MSIO connections, then the multiplexer 113 may configure more MSIO lanes 48 for HVIO connections in comparison to MSIO connections. With the dual bump design, the first integrated circuit 12 may support both MSIO connections and HVIO connections, thereby providing flexibility to select between the MSIO applications, the HVIO applications, or both.

In certain instances, the second integrated circuit 14 may fail or may not operate as expected. If the second integrated circuit 14 fails and/or does not operate, then the same MSIO lane 48 may be used for the MSIO connections. For example, the multiplexer 113 may only couple to the MSIO interface 106. As such, the integrated circuit device 10 may not experience yield loss due to HVIO chiplet loss.

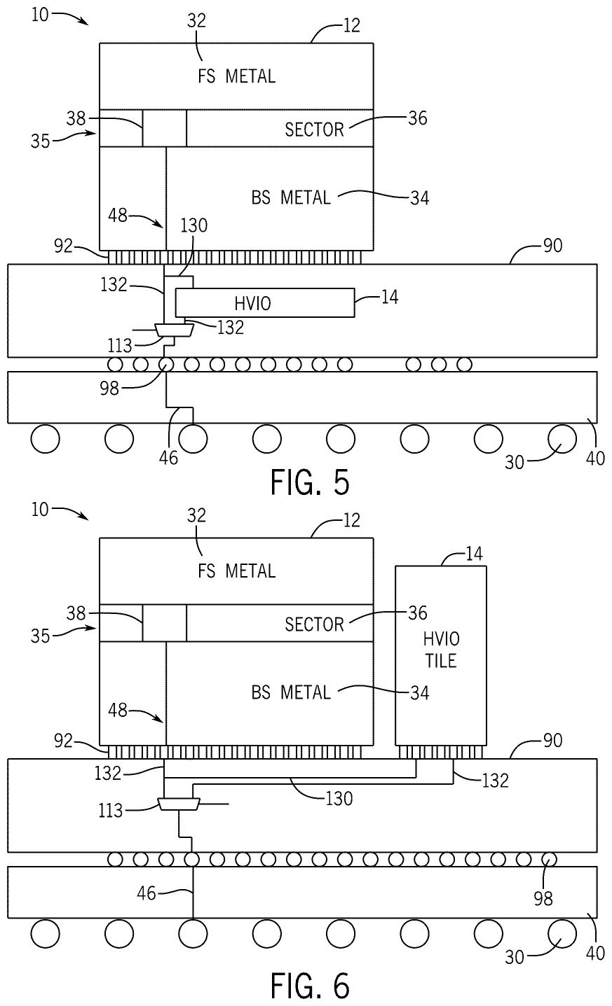

FIG. 5 is a schematic diagram of an embodiment of the integrated circuit device 10 with the first integrated circuit 12 and the second integrated circuit 14. The schematic diagram of FIG. 4 illustrates a cross-sectional view of the first integrated circuit 12 attached to the interposer 90 and the second integrated circuit 14 disposed within (e.g., implemented by) the interposer 90. For example, the interposer 90 may include an active interposer to provide one or more functionalities of the integrated circuit device 10. By positioning the second integrated circuit 14 within the interposer 90, the size of the integrated circuit device 10 may be reduced and/or increasing the amount silicon area of the interposer 90 for coupling to components.

As illustrated, the first integrated circuit 12 may be attached to the interposer 90 via microbumps 92 and the second integrated circuit 14 may be positioned within the interposer 90. The interposer 90 may include a first set of traces 130 to couple the first integrated circuit 12 to the second integrated circuit 14. As such, the interposer 90 may facilitate signal transfer and/or power between the two.

The interposer 90 may include a second set of traces 132 coupling the first integrated circuit 12 and the second integrated circuit 14 to a multiplexer (e.g., mux) 113. The multiplexer 113 may include two inputs and one output. The multiplexer 113 may be coupled to the first integrated circuit 12 and the second integrated circuit 14 as the inputs and the BGA ball 30 as the output. The multiplexer 113 may support a maximum voltage of the IO between the MSIO pins 38 and the second integrated circuit 14 (e.g., HVIO OPIO). For example, the multiplexer 113 may include a thick gate that handles high voltages. The multiplexer 113 may be coupled to a single BGA ball 30 via a PSB 98 and/or the package substrate 40 for package connection. As discussed herein, the multiplexer 113 may receive user input and selectively couple either the first integrated circuit 12 or the second integrated circuit 14 to the BGA ball 30 based on the user input.

Using the multiplexer 113, the MSIO lane 48 may couple to one microbump 92, which may increase a number of microbumps 92 available for coupling to other components of the integrated circuit device 10. Moreover, by using the dual bump design, the amount of space used for both the MSIO connections and the HVIO connections may be reduced, thereby decreasing a size of the integrated circuit device 10. For example, since the MSIO lane 48 couples to one BGA ball 30, the number of BGA balls 30 used for the MSIO applications and the HVIO applications may be reduced by half or by a ratio of 2:1. As such, the number of BGA balls 30 available for coupling may increase. For example, multiplexing (muxing) the HVIO output and the MSIO output in the interposer 90 prior to communicating with off-package components may reduce the number of BGA balls 30 used in the integrated circuit device 10.

As discussed herein, the multiplexer 113 may be coupled to power control circuitry and/or a voltage regulator. The power control circuitry and/or the voltage regulator may be disposed within the interposer 90 and provide a voltage supply to the multiplexer 113. For example, the power control circuitry may vary the voltage supply received by the multiplexer 113 based on an input. The inputs may include an MSIO connection, an HVIO connection, or both. Additionally or alternatively, the interposer 90 may include level shifters for the MSIO connection, the HVIO connection, or both. The level shifters may provide a voltage level corresponding to the high voltage of the second integrated circuit 14 and/or a lower voltage of the first integrated circuit 12.

FIG. 6 is a schematic diagram of an embodiment of the integrated circuit device 10 with the first integrated circuit 12 and the second integrated circuit 14. The embodiment of the integrated circuit device 10 of FIG. 6 is substantially similar to the integrated circuit device of FIG. 5 except that the second integrated circuit 14 is attached to the interposer 90 via the microbumps 92. The first integrated circuit 12 and the second integrated circuit 14 may be communicatively coupled via a first set of traces 130 of the interposer 90, and the first integrated circuit 12 and the second integrated circuit 14 may be respectively coupled to the multiplexer 113 via the second set of traces 132.

The interposer 90 may include an active interposer to provide mux logic (as illustrated by the multiplexer 113) to select between the MSIO output and the HVIO output based on user input, thereby providing modular and scalable design for the integrated circuit device 10. That is, the multiplexer 113 may selectively couple the first integrated circuit 12 or the second integrated circuit 14 to the BGA ball 30 to provide MSIO connections or HVIO connections.

FIG. 7 is a schematic diagram of an embodiment of the integrated circuit device 10 with the first integrated circuit 12 and the second integrated circuit 14. The embodiment of the integrated circuit device 10 of FIG. 7 is substantially similar to the integrated circuit device of FIG. 6 except that the interposer 90 includes an additional second integrated circuit 14B disposed within (e.g., implemented by) the interposer 90. For example, the first integrated circuit 12 may be coupled to the second integrated circuit 14 via the first set of traces 130 of the interposer 90, and first integrated circuit 12 and the second integrated circuit 14 may be coupled to the multiplexer 113 via the second set of traces 132. The multiplexer 113 may selectively couple either the first integrated circuit 12 or the second integrated circuit 14 to a first BGA ball 30A based on user input.

The first integrated circuit 12 may include additional MSIO pins 38B. In an example, the additional MSIO pins 38B may be implemented in the same sector 36 as the MSIO pins 38A. In another example, the additional MSIO pins 38B may be implemented in a different sector 36 as the MSIO pins 38A and provide voltage operations in the different sector 36. To this end, the MSIO pins 38B may be coupled to a second BGA ball 30B via a microbump 92, the interposer 90, a PSB 98, and the package substrate 40.

The interposer 90 may include and/or implement an additional second integrated circuit 14A and an additional multiplexer 134 to provide additional MSIO applications, HVIO applications, or both to the integrated circuit device 10. The first integrated circuit 12 may couple to the second integrated circuit 14 via the first set of traces 130 of the interposer 90. The first integrated circuit 12 and the second integrated circuit 14 may couple to the additional multiplexer 134 via the second set of traces of the interposer 90. The additional multiplexer 134 may selectively couple the additional MSIO pins 38 or the additional second integrated circuit 14B to the second BGA ball 30B based on user input. The second BGA ball 30B may implement the first functionality, the second functionality, or both based on the user input.

As discussed herein, the interposer 90 may include power control circuitry, a voltage regulation, and/or level shifters to adjust a voltage supply to the multiplexer 113 and/or the additional multiplexer 134. For example, the voltage supply to the multiplexer 113 and/or the additional multiplexer 134 may be adjusted based on an input.

Although the illustrated embodiment of the integrated circuit device 10 of FIG. 7 includes an additional second integrated circuit 14B coupled to the interposer 90, it may be understood that the integrated circuit device 10 may include any suitable number of second integrated circuits and/or multiplexers 113 to selectively couple the first integrated circuit 12 or the second integrated circuit 14 to a BGA ball 30. As such, the integrated circuit device 10 may selectively perform MSIO applications, HVIO applications, or both, thereby increasing flexibility of the integrated circuit device 10.

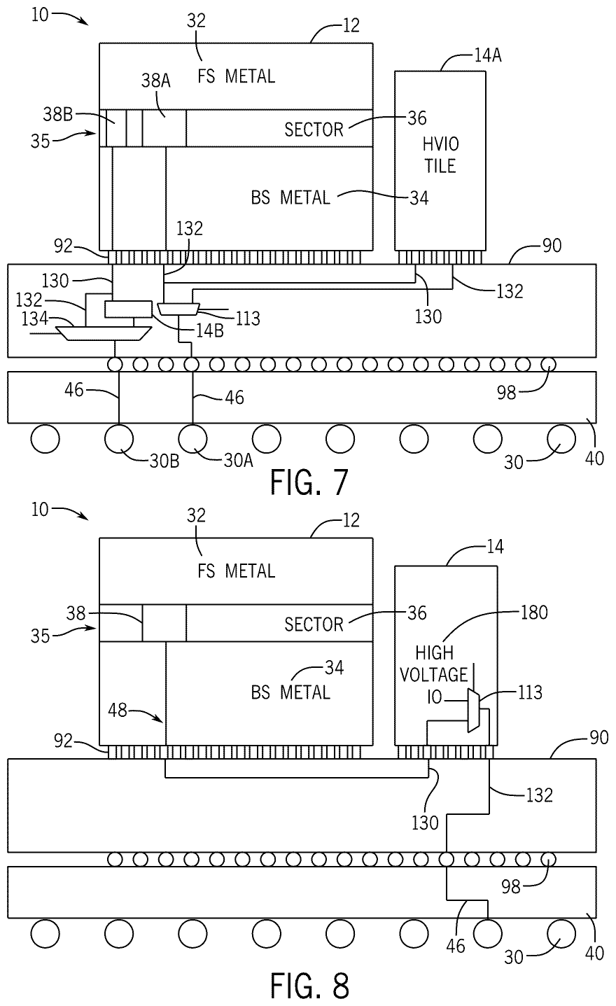

FIG. 8 is a schematic diagram of an embodiment of the integrated circuit device 10 with the first integrated circuit 12 and the second integrated circuit 14. The schematic diagram of FIG. 7 illustrates a cross-sectional view of the first integrated circuit 12 and the second integrated circuit 14, which includes the multiplexer 113 to select between the MSIO output and/or HVIO output based on user input.

The first integrated circuit 12 and the second integrated circuit 14 may be communicatively coupled via the first set of traces 130 of the interposer 90. The interposer 90 may include a passive interposer, which may reduce manufacturing costs of the integrated circuit device 10 of FIG. 8.

The second integrated circuit 14 may include and/or implement the multiplexer 113 to selectively couple between the MSIO output and the HVIO output. The multiplexer 113 may include power mux and/or data mux that selects between an output the first integrated circuit 12 and an output the second integrated circuit 14 based on user input. That is, the multiplexer 113 may selectively couple the MSIO pins 38 to the BGA ball 30 or the HVIO OPIO to the BGA ball 30 based on the user input. To this end, the multiplexer 113 may include a first input coupled to a high voltage source 180 and a second input coupled to the MSIO pins 38 via the first set of traces 130. The multiplexer 113 may include one output coupled to a BGA ball 30.

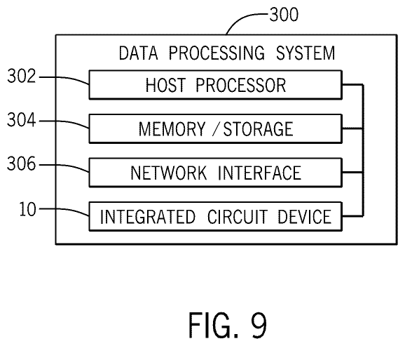

Bearing the foregoing in mind, the integrated circuit device 10 may be a component included in a data processing system and/or data center, such as a data processing system 300, shown in FIG. 9. The data processing system 300 may include the integrated circuit device 10, a host processor 302 (e.g., a processor), memory and/or storage circuitry 304, and a network interface 306. The data processing system 300 may include more or fewer components (e.g., electronic display, designer interface structures, ASICs). Moreover, any of the circuit components depicted in FIG. 9 may include integrated circuits (e.g., integrated circuit device 10). The host processor 302 may include any of the foregoing processors that may manage a data processing request for the data processing system 300 (e.g., to perform encryption, decryption, machine learning, video processing, voice recognition, image recognition, data compression, database search ranking, bioinformatics, network security pattern identification, spatial navigation, cryptocurrency operations, or the like). The memory and/or storage circuitry 304 may include random access memory (RAM), read-only memory (ROM), one or more hard drives, flash memory, or the like. The memory and/or storage circuitry 304 may hold data to be processed by the data processing system 240. In some cases, the memory and/or storage circuitry 304 may also store configuration programs (bit streams) for programming one or more components of the integrated circuit device 10. The network interface 306 may allow the data processing system 300 to communicate with other electronic devices. The data processing system 240 may include several different packages or may be contained within a single package on a single package substrate. For example, components of the data processing system 300 may be located on several different packages at one location (e.g., a data center) or multiple locations. For instance, components of the data processing system 300 may be located in separate geographic locations or areas, such as cities, states, or countries.

In one example, the data processing system 300 may be part of a data center that processes a variety of different requests. For instance, the data processing system 300 may receive a data processing request via the network interface 306 to perform encryption, decryption, machine learning, video processing, voice recognition, image recognition, data compression, database search ranking, bioinformatics, network security pattern identification, spatial navigation, digital signal processing, or some other specialized task.

The above discussion has been provided by way of example. Indeed, the embodiments of this disclosure may be susceptible to a variety of modifications and alternative forms. As discussed herein, the first integrated circuit 12 may include any suitable number of MSIO lanes that implement the dual bump design to facilitate MSIO BGA connections, HVIO OPIO connections, or both. Furthermore, the integrated circuit device 10 may include any suitable number of second integrated circuit 14 coupled to the interposer 90, disposed within and/or implemented by the interposer 90, or both.

While the embodiments set forth in the present disclosure may be susceptible to various modifications and alternative forms, specific embodiments have been shown by way of example in the drawings and have been described in detail herein. However, it should be understood that the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112 (f). However, for any claims containing elements designated in any other manner, it is intended that such elements are not to be interpreted under 35 U.S.C. 112 (f).

### EXAMPLE EMBODIMENTS

EXAMPLE EMBODIMENT 1. EXAMPLE EMBODIMENT 1. A multi-die package, including a plurality of a ball grid array (BGA) balls to provide signal transfer, a first integrated circuit comprising an input/output (IO) circuit to perform a first set of operations using a first voltage and coupled to a first BGA ball of the plurality of BGA balls, and a second integrated circuit coupled to the IO circuit and a second BGA of the plurality of BGA balls, wherein the second integrated circuit performs a second set of operations using a second voltage greater than the first voltage, and wherein the first integrated circuit selectively couples an input from the first BGA ball or an input from the second BGA ball.

EXAMPLE EMBODIMENT 2. The multi-die package of example embodiment 1, wherein the IO circuit drives the first BGA ball and the second BGA ball at the second voltage.

EXAMPLE EMBODIMENT 3. The multi-die package of example embodiment 1, comprising a package substrate including a first interface coupled to the first integrated circuit and the second integrated circuit via a plurality of controlled collapse chip connection (C4) bumps on a surface of the package substrate, wherein the first integrated circuit couples to two C4 bumps of the plurality of C4 bumps; and a second interface coupled to plurality of BGA balls.

EXAMPLE EMBODIMENT 4. The multi-die package of example embodiment 2, wherein the first integrated circuit receives an output from the second integrated circuit via a first C4 bump of the two C4 bumps.

EXAMPLE EMBODIMENT 5. The multi-die package of example embodiment 3, the first integrated circuit comprises a multiplexer to selectively couple the input from the first BGA ball or the input from the second BGA ball.

EXAMPLE EMBODIMENT 6. The multi-die package of example embodiment 1, comprising an interposer mounted onto a package substrate, wherein the interposer including a first interface coupled to the first integrated circuit and the second integrated circuit via a plurality of microbumps, wherein the first integrated circuit receives an output from the second integrated circuit via a first microbump and couples to the BGA ball via a second microbump; and a second interface coupled to the package substrate.

EXAMPLE EMBODIMENT 7. The multi-die package of example embodiment 1, wherein the second integrated circuit receives an input from a second BGA ball of the plurality of BGA balls.

EXAMPLE EMBODIMENT 8. A multi-die package including a package substrate coupled to a plurality of ball grid array (BGA) balls to provide signal transfer; an interposer mounted onto the package substrate; a first integrated circuit mounted onto the interposer and operating at a first voltage; a second integrated circuit coupled to the first integrated circuit and operating at a second voltage greater than the first voltage; and a multiplexer coupled to the first integrated circuit and the second integrated circuit, wherein the multiplexer selectively couples the first integrated circuit or the second integrated circuit to a first BGA ball of the plurality of BGA balls.

EXAMPLE EMBODIMENT 9. The multi-die package of example embodiment 8, wherein the second integrated circuit and the multiplexer are disposed within the interposer.

EXAMPLE EMBODIMENT 10. The multi-die package of example embodiment 9, wherein the second integrated circuit receives an output of the first integrated circuit and transmits the output of the first integrated circuit and an output from the second integrated circuit to the multiplexer.

EXAMPLE EMBODIMENT 11. The multi-die package of example embodiment 8, wherein the second integrated circuit is mounted onto the interposer and the multiplexer is disposed within the interposer.

EXAMPLE EMBODIMENT 12. The multi-die package of example embodiment 11, including an additional second integrated circuit coupled to the first integrated circuit, wherein the additional second integrated circuit is disposed within the interposer; and an additional multiplexer coupled to the additional second integrated circuit and the first integrated circuit, wherein the additional multiplexer selectively couples selectively couples either the first integrated circuit or the additional second integrated circuit to a second BGA ball of the plurality of BGA balls based on additional user input.

EXAMPLE EMBODIMENT 13. The multi-die package of example embodiment 8, wherein the interposer comprises a plurality of level shifters to adjust the range of voltages provided by the interposer to the first voltage based on the multiplexer coupling to the first integrated circuit and the second voltage based on the multiplexer coupling to the second integrated circuit.

EXAMPLE EMBODIMENT 14. A multi-die package including a first integrated circuit comprising an input/output (IO) circuit operating at a first voltage; and a high voltage input/output (HVIO) circuit coupled to the first integrated circuit, wherein the HVIO circuit operates at a second voltage greater than the first voltage; and a multiplexer coupled to the first integrated circuit and the HVIO circuit, wherein the multiplexer selectively couples the first integrated circuit or the HVIO circuit to a ball grid array (BGA) ball.

EXAMPLE EMBODIMENT 15. The multi-die package of example embodiment 14, wherein the HVIO circuit is implemented in a chiplet.

EXAMPLE EMBODIMENT 16. The multi-die package of example embodiment 15, wherein the multiplexer receives an output from the first integrated circuit as a first input and an output from the chiplet as a second input.

EXAMPLE EMBODIMENT 17. The multi-die package of example embodiment 15, wherein the multiplexer is disposed within the chiplet.

EXAMPLE EMBODIMENT 18. The multi-die package of example embodiment 14, wherein the multiplexer is implemented in an interposer, and wherein the first integrated circuit and the HVIO circuit are mounted onto the interposer.

EXAMPLE EMBODIMENT 19. The multi-die package of example embodiment 18, including an additional HVIO circuit implemented in a second integrated circuit and mounted onto the interposer, wherein the additional HVIO circuit operates at the second voltage; and an additional multiplexer implemented by the interposer and communicatively coupled to the first integrated circuit and the additional HVIO circuit, wherein the additional multiplexer selectively couples the first integrated circuit or the additional HVIO circuit to an additional BGA ball.

EXAMPLE EMBODIMENT 20. The multi-die package of example embodiment 14, wherein the HVIO circuit and the multiplexer are implemented in an interposer.

What is claimed is:

1. A multi-die package, comprising:
a plurality of a ball grid array (BGA) balls to provide signal transfer;
a first integrated circuit comprising an input/output (IO) circuit to perform a first set of operations using a first voltage and coupled to a first BGA ball of the plurality of BGA balls; and
a second integrated circuit coupled to the IO circuit and a second BGA of the plurality of BGA balls, wherein the second integrated circuit performs a second set of operations using a second voltage greater than the first voltage, and
wherein the first integrated circuit selectively couples an input from the first BGA ball or an input from the second BGA ball.

2. The multi-die package of claim 1, wherein the IO circuit drives the first BGA ball and the second BGA ball at the second voltage.

3. The multi-die package of claim 1, comprising a package substrate comprising:
a first interface coupled to the first integrated circuit and the second integrated circuit via a plurality of controlled collapse chip connection (C4) bumps on a surface of the package substrate, wherein the first integrated circuit couples to two C4 bumps of the plurality of C4 bumps; and
a second interface coupled to plurality of BGA balls.

4. The multi-die package of claim 2, wherein the first integrated circuit receives an output from the second integrated circuit via a first C4 bump of the two C4 bumps.

5. The multi-die package of claim 3, the first integrated circuit comprises a multiplexer to selectively couple the input from the first BGA ball or the input from the second BGA ball.

6. The multi-die package of claim 1, comprising an interposer mounted onto a package substrate, wherein the interposer comprises:
a first interface coupled to the first integrated circuit and the second integrated circuit via a plurality of microbumps, wherein the first integrated circuit receives an output from the second integrated circuit via a first microbump and couples to the BGA ball via a second microbump; and
a second interface coupled to the package substrate.

7. The multi-die package of claim 1, wherein the second integrated circuit receives an input from a second BGA ball of the plurality of BGA balls.

8. A multi-die package, comprising:
a package substrate coupled to a plurality of ball grid array (BGA) balls to provide signal transfer;
an interposer mounted onto the package substrate;
a first integrated circuit mounted onto the interposer and operating at a first voltage;
a second integrated circuit coupled to the first integrated circuit and operating at a second voltage greater than the first voltage; and
a multiplexer coupled to the first integrated circuit and the second integrated circuit, wherein the multiplexer selectively couples the first integrated circuit or the second integrated circuit to a first BGA ball of the plurality of BGA balls.

9. The multi-die package of claim 8, wherein the second integrated circuit and the multiplexer are disposed within the interposer.

10. The multi-die package of claim 9, wherein the second integrated circuit receives an output of the first integrated circuit and transmits the output of the first integrated circuit and an output from the second integrated circuit to the multiplexer.

11. The multi-die package of claim 8, wherein the second integrated circuit is mounted onto the interposer and the multiplexer is disposed within the interposer.

12. The multi-die package of claim 11, comprising:
an additional second integrated circuit coupled to the first integrated circuit, wherein the additional second integrated circuit is disposed within the interposer; and
an additional multiplexer coupled to the additional second integrated circuit and the first integrated circuit, wherein the additional multiplexer selectively couples selectively couples either the first integrated circuit or the additional second integrated circuit to a second BGA ball of the plurality of BGA balls based on additional user input.

13. The multi-die package of claim 8, wherein the interposer comprises a plurality of level shifters to adjust the range of voltages provided by the interposer to the first voltage based on the multiplexer coupling to the first integrated circuit and the second voltage based on the multiplexer coupling to the second integrated circuit.

14. A multi-die package comprising:
a first integrated circuit comprising an input/output (IO) circuit operating at a first voltage; and
a high voltage input/output (HVIO) circuit coupled to the first integrated circuit, wherein the HVIO circuit operates at a second voltage greater than the first voltage; and
a multiplexer coupled to the first integrated circuit and the HVIO circuit, wherein the multiplexer selectively couples the first integrated circuit or the HVIO circuit to a ball grid array (BGA) ball.

15. The multi-die package of claim 14, wherein the HVIO circuit is implemented in a chiplet.

16. The multi-die package of claim 15, wherein the multiplexer receives an output from the first integrated circuit as a first input and an output from the chiplet as a second input.

17. The multi-die package of claim 15, wherein the multiplexer is disposed within the chiplet.

18. The multi-die package of claim 14, wherein the multiplexer is implemented in an interposer, and wherein the first integrated circuit and the HVIO circuit are mounted onto the interposer.

19. The multi-die package of claim 18, comprising:
an additional HVIO circuit implemented in a second integrated circuit and mounted onto the interposer, wherein the additional HVIO circuit operates at the second voltage; and
an additional multiplexer implemented by the interposer and communicatively coupled to the first integrated circuit and the additional HVIO circuit, wherein the additional multiplexer selectively couples the first integrated circuit or the additional HVIO circuit to an additional BGA ball.

20. The multi-die package of claim 14, wherein the HVIO circuit and the multiplexer are implemented in an interposer.
